(19) United States
(12) Patent Application Publication
(10) Pub. No.: US 2004/0152317 A1
(43) Pub. Date: Aug. 5, 2004

(54) Method and structures for increasing the structure density and the storage capacitance in a semiconductor wafer

(76) Inventors: Joern Luetzen, Dresden (DE); Albert Birner, Dresden (DE); Stephan Kudelka, Ottendorf-Okrilla (DE); Helmut Tews, Munich (DE); Rolf Weis, Dresden (DE)

Correspondence Address: Michael A. Oblon, SHAW PITTMAN LLP, 1650 Tysons Boulevard, McLean, VA, 22102, US

(21) Appl. No.: 10/721,225

(22) Filed: Nov. 26, 2003

(30) Foreign Application Priority Data
Nov. 29, 2002 (DE) 102 55 866.3

(51) Int. Cl. H01L 21/302; H01L 21/461

(52) U.S. Cl. 438/689

(57) ABSTRACT

Method for increasing the structure density and/or the storage capacitance of structures to be introduced into a semiconductor wafer, the semiconductor wafer having a marking. prescribing a breaking direction and the structures being imaged onto the semiconductor wafer by means of an exposure device and a mask, whose mask layout prescribes the structures. The semiconductor wafer is rotated by 45 degrees in its plane with regard to the mask layout prior to the imaging of the structures and provided with a marking prescribing a new breaking direction parallel to a <100> crystal orientation. The further process steps take place unchanged with respect to nonrotated semiconductor wafers.

### BACKGROUND

1. Field of the Invention

The present invention relates generally to semiconductor fabrication and semiconductor structures.

2. Background Information

DRAM (dynamic random access memories) modules are a mass-produced product with many applications. On the one hand, smaller dimensions and, on the other hand, a higher number of memory cells for storing data, that is to say an increasing storage density, are demanded of new generations of DRAM modules. This results in the need to further reduce the cell size of an individual memory cell, comprising a storage capacitance and a selection transistor. Depending on the arrangement of the storage capacitance in or above a metalization plane, a distinction is made between memory cells of the “stacked capacitor” type and “trench capacitor” type. In the case of a memory cell of the “trench capacitor” type, a trench is formed in a monocrystalline semiconductor substrate of a semiconductor wafer below a metalization plane.

A dielectric, for example a nitride/oxide layer system, is provided along the trench wall. In the monocrystalline semiconductor substrate, a region which is doped by outdiffusion, for instance, and adjoins the trench forms a first electrode. In the trench, a counterelectrode is formed by deposition of highly doped polycrystalline silicon.

Reducing the cell size leads to trenches with a smaller electrode area and thus to storage capacitances having a lower electrical capacitance. In order to compensate for the loss of capacitance, it is necessary to increase the capacitance again in a different way by means of complicated new process technologies. Examples thereof are a higher doping of the electrodes in order to reduce the charge carrier depletion, the use of dielectrics with a high dielectric constant and the application of additional structures (HSG, hemispherical grains) on the trench wall in order to enlarge the surface.

A further possibility for increasing the capacitance consists in increasing the surface of the trench by means of a bottle-like extension in a lower section of the trench. The trench thus extends in the depth of the semiconductor substrate also partly into regions of the semiconductor substrate located below the selection transistors formed on the surface of the semiconductor substrate.

FIGS. 4A-C show plan view recordings taken by a scanning electron microscope, abbreviated to SEM hereinafter, of trenches of storage capacitances in different depths of a semiconductor substrate, said trenches being arranged in checkered fashion in alternation with unpatterned fields. The recordings each show an arrangement of structures which are based on a rectangular pattern in a mask layout and are transferred and etched into a semiconductor substrate in a conventional manner.

FIG. 4A shows upper sections 8 of trenches of storage capacitances in the vicinity of the surface of the semiconductor substrate 6, said sections being provided with a protective layer that is resistant toward a bottle etching process.

A profile with a bottle-like extension 5 which is shown in FIG. 4B is produced in each case in sections of the trenches formed below the protective layer. Between the sidewalls 7 of adjacent trenches, intermediate walls are formed from the material of the semiconductor substrate 6. The extent of the bottle-like extension 5 is limited by the demand for a minimum thickness of the intermediate walls. An excessively small thickness of the intermediate wall leads to a higher number of short circuits between the storage capacitances of adjacent memory cells on account of manufacturing tolerances.

FIG. 4C represents the trenches in the region of a trench bottom 9 which terminates the trenches in the depth of the semiconductor substrate 6. They have a rectangular form with a smaller cross-sectional area than directly below the protective layer.

Overall, FIGS. 4A-C reveal, on the one hand, that although the electrode surface of the storage capacitance is enlarged by the bottle-like extension of the trench, on the other hand, the extent of the bottle-like extension is limited.

There is, accordingly, a need to provide improved fabrication techniques and structures for increasing storage capacitance.

### SUMMARY

The present invention is based on the object of providing a method and a structure with which it is possible to further increase a structure density and/or a storage capacitance of an individual structure in a semiconductor substrate compared with conventional methods and structures.

The invention provides for a method for increasing a structure size of main structures—formed in essential parts in a depth of a semiconductor substrate—by means of an etching process which expands the main structures in the depth of the semiconductor substrate, provision being made of the semiconductor substrate comprising a crystalline material with a crystal lattice with crystal faces that are more resistant to etching and with crystal faces that are less resistant to etching, and the main structures being arranged in checkered fashion in a rectangular surface grid, at a surface of the semiconductor substrate, in each case in alternation with secondary structures formed in each case essentially in a section of the semiconductor substrate that is near the surface.

The invention is explained below with reference to figures, identical reference symbols being used for mutually corresponding components.

### BRIEF DESCRIPTION OF THE DRAWINGS

FIG. 1 shows a diagrammatic illustration of an arrangement comprising mask and semiconductor wafer for carrying out the method according to the invention,

FIG. 2 shows a diagrammatic illustration of an arrangement comprising mask and semiconductor wafer for carrying out a conventional method,

FIG. 3 shows a diagrammatic longitudinal section through a trench etched into a semiconductor substrate,

FIGS. 4A-C show SEM plan view recordings of trenches in a semiconductor wafer in different depths,

FIGS. 5A-D show SEM plan view recordings of structures according to the invention in a semiconductor wafer in different depths,

FIGS. 6A-F show SEM plan view recordings of structures according to the invention in a semiconductor wafer before and after a bottle etching in different depths,

FIGS. 7A-B show diagrammatic plan views of surfaces of a semiconductor substrate processed conventionally and of a semiconductor substrate processed according to the invention, and

FIG. 8 shows an illustration of the functional dependence of the number of discharged memory cells AS on the time t_{Ret} in the case of semiconductor wafers processed according to the invention and in the case of semiconductor wafers processed conventionally.

### DETAILED DESCRIPTION

A list of reference numerals used in the following description is provided below:

1 Semiconductor wafer

2 Marking

3 Mask

4 Trench

5 Extension

6 Semiconductor substrate

7 <110> sidewall

8 Upper part of the trench

9 Trench in the region of the trench bottom

10 Trench at the surface

11 <100> sidewall

12 Trench below the protective layer

131 Main structure

132 Secondary structure

14 Surface grid

151 Field for main structure

152 Field for secondary structure

161 Field for main structure below structure edge

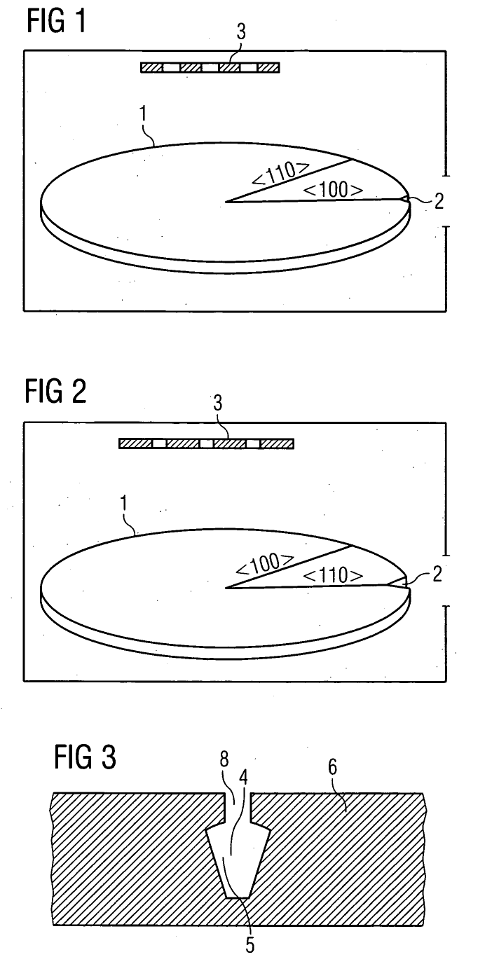

For the method according to the invention, a mask 3 and a semiconductor wafer 1 made of monocrystalline silicon are arranged in the manner shown in FIG. 1. The semiconductor wafer 1 is provided with a marking 2 according to the invention, which marking is rotated by 45 degrees with respect to conventionally marked semiconductor wafers and identifies the <100> crystal orientation of the silicon. By means of the marking, the mask is oriented to the crystal orientation in the semiconductor wafer. The mask structure is thus imaged along a different crystal orientation compared with conventional methods.

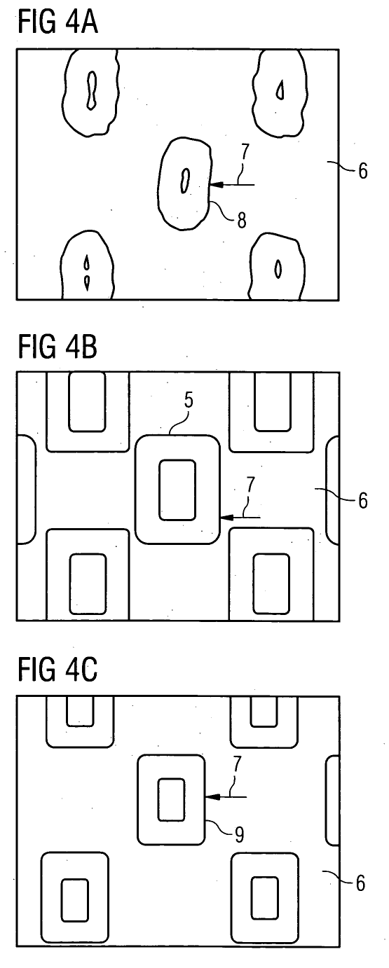

For comparison purposes, an arrangement corresponding to the prior art is illustrated in FIG. 2. Here the semiconductor wafer 1 is provided with a marking 2 pointing in the <110> crystal orientation.

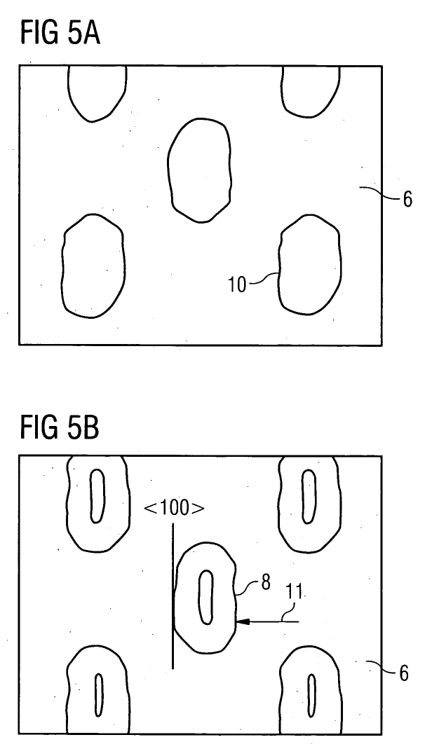

FIG. 3 shows a structure which is etched into a semiconductor substrate 6 and is designed as a trench 4. On account of a further etching step below a trench depth of about one micrometer, the trench has a bottle-like extension 5 for enlarging an electrode area of a storage capacitance to be processed from the trench. The upper section of the trench 8 is provided with a protective layer which prevents lateral etching into the semiconductor substrate 6 in regions near the surface.

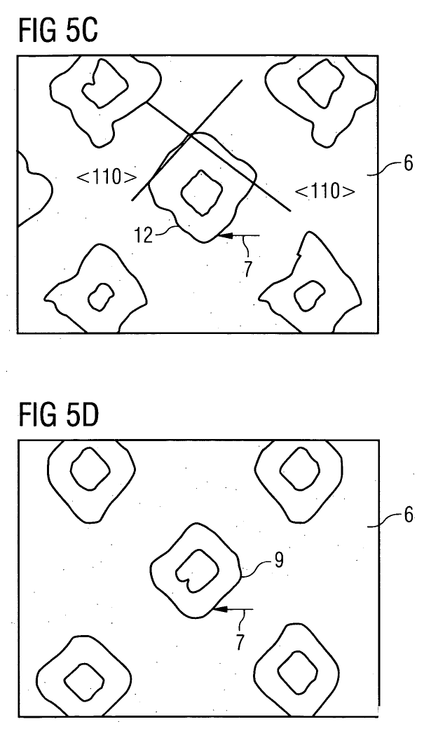

As previously explained, trenches of the type described can be seen in plan view in FIG. 4. The trenches were imaged onto a nonrotated semiconductor wafer using a checkered mask layout and subsequently etched into the semiconductor substrate 6.

FIG. 4A illustrates the upper parts—provided with a protective layer—of the trenches 8, the sidewalls of which form an oval and the long side of which is arranged parallel to the <110> crystal orientation. Such a side is called <110> sidewall 7 for short hereinafter.

Deeper in the semiconductor substrate, approximately where the protective layer ends, the cross section illustrated in FIG. 4B results, said cross section showing a bottle-like extension 5. Below the protective layer, the sidewalls form a rectangle with <110> sidewalls 7. Intermediate walls formed from the semiconductor substrate 6 between the sidewalls of the individual trenches 8 have, at their thinnest points, a very small thickness of approximately 20 nanometers, which can lead to short circuits in the case of trenches processed to form storage capacitances, on account of manufacturing tolerances.

FIG. 4C represents the trenches in the region of a trench bottom 9 terminating the trenches in the depth of the semiconductor substrate. There they have a rectangular form with a smaller cross-sectional area than directly below the protective layer. The sidewalls are again <110> sidewalls 7.

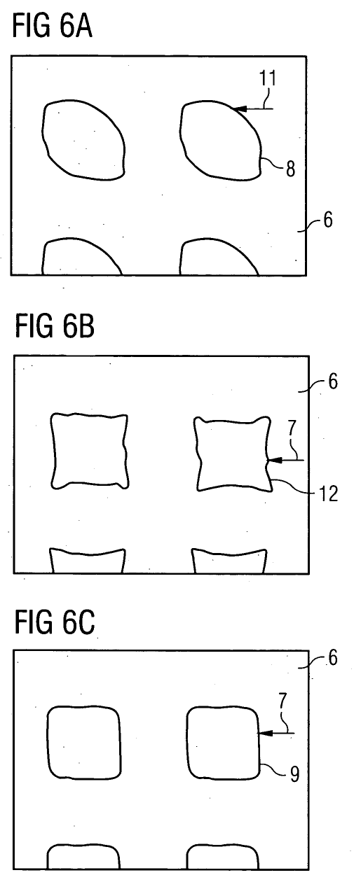

The trenches shown in FIGS. 5A-D were produced by the method according to the invention. They are based on the same checkered mask layout of FIG. 4. For this purpose, the mask layout is imaged onto a semiconductor wafer oriented according to the invention. Afterward, the trenches are etched into the semiconductor substrate 6 and each provided with a protective layer in upper sections. FIGS. 5A to 5D illustrate cross sections of the trenches in different depths parallel to the surface 10 of the semiconductor substrate 6.

In this case, FIG. 5A shows a plan view of the trenches at the surface 10 of the semiconductor substrate 6. FIG. 5B shows a cross section through the trenches in the region of the protective layer below the surface 10. The sidewalls of the upper sections of the trenches in each case form an oval whose long sides are oriented according to the invention parallel to the <100> crystal orientation. Such a side is called <100> sidewall 11 for short hereinafter. FIGS. 5C and 5D represent the cross sections of the trenches below the protective layer 12 in two different depths. The sidewalls of the trenches form a square with <110> sidewalls 7 in cross section. The sidewalls of the upper section of a trench are thus rotated by 45 degrees with respect to the sidewalls of the lower section of the same trench. As can be seen when comparing FIG. 4C with FIG. 5D, the resulting rotated square cross section of the trenches in the region below the protective layer leads to an improved utilization of the area of the semiconductor substrate 6.

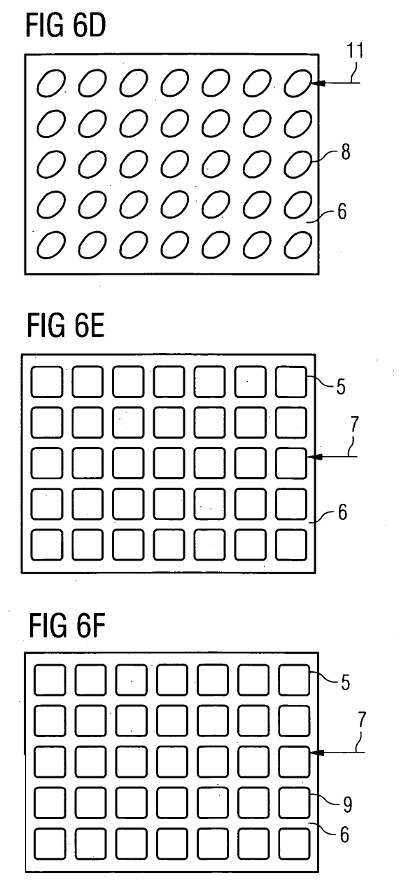

The improved utilization of area becomes clear from FIGS. 6A-F. The cross sections of the trenches produced according to the invention in FIGS. 6A to 6C were recorded before the etching step (bottle etch)—leading to the bottle-like extension—in different depths and correspond to the cross sections of the trenches in FIGS. 5B to 5C.

The cross sections of the trenches after the etching step leading to the bottle-like extension can be seen on a larger scale in FIGS. 6D to 6F. The cross section—oval in plan view—in the upper section of the trenches with <100> sidewalls 11 is shown in FIG. 6D. FIGS. 6E and 6F show the square cross sections with <110> sidewalls 7 of the bottle-like extensions in two different depths, one above and one below the trench center. The perfect utilization of area in the depth of the semiconductor substrate can clearly be discerned here.

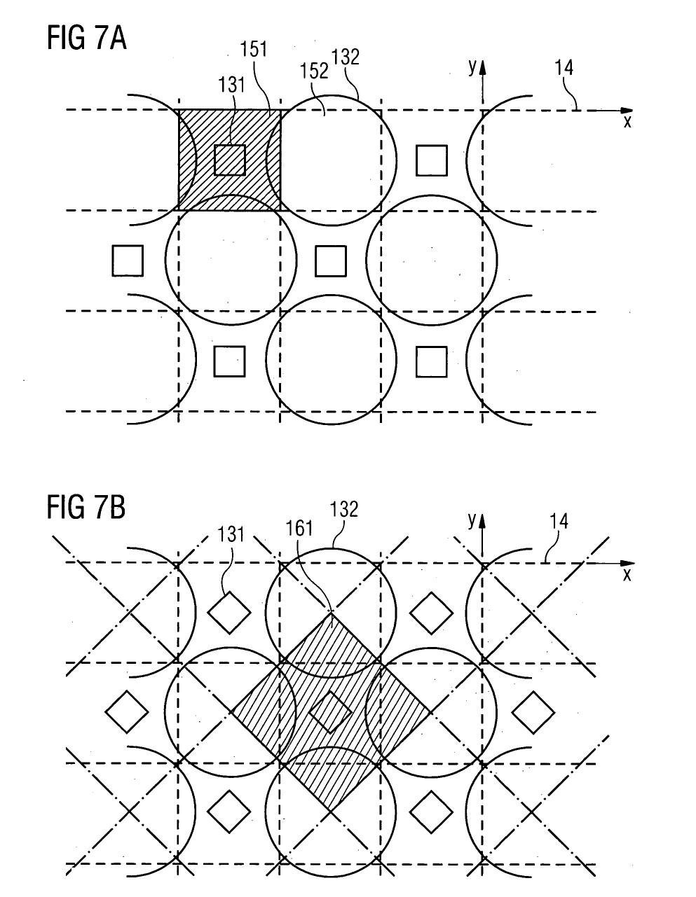

The better utilization of a semiconductor substrate 6 by the method according to the invention is also illustrated with reference to FIGS. 7A-B.

A pattern of main and secondary structures 131, 132 is formed on a surface of the semiconductor substrate 6, said pattern being oriented along a surface grid 14. The main and secondary structures 131, 132 are arranged alternately in checkered fashion in the surface grid 14.

The surface grid 14 forms equally sized square fields 151, 152 in this example for illustration purposes. However, the method according to the invention also leads to an advantageous utilization of the semiconductor substrate 6 in the case of other divisions with unequally sized or expanded fields.

The secondary structures 132 are essentially arranged in a section of the semiconductor substrate 6 near the surface between the surface of the semiconductor substrate 6 and a structure edge in the depth of the semiconductor substrate 6. By contrast, substantial parts of the main structures 131 are formed below the structure edge. The main structures 131 are conventionally expanded below the structure edge by means of a bottle etching process. After being expanded, the main structures 131 also extend, as illustrated in FIG. 7A, into sections of the semiconductor substrate 6 which lie below the secondary structures 132.

In this case, the bottle etching process extends the main structures 131 in a manner independent of direction, so that the maximum possible extension of a main structure 131 is also restricted in the depth of the semiconductor substrate 6 to a field 151 assigned to the main structure 131. Sections of the semiconductor substrate which extend below the structure edge under fields 152 assigned to the secondary structures remain unused.

By contrast, those sections of the semiconductor substrate 6 below the substrate edge which are arranged below the fields 152 assigned to the secondary structures 132 are also made available, by the method according to the invention, for extension of the main structures 131.

For this purpose, as illustrated in FIG. 7B, the surface grid 14 is oriented parallel to crystal faces of the semiconductor substrate 6 that are less resistant to etching. In the course of an area-selective etching process, the main structures 131 are formed in the depth of the semiconductor substrate 6 below the structure edge with sidewalls that are ideally rotated by 45 degrees with respect to the surface grid 14. If the rotated main structures 131 are subsequently expanded by means of a bottle etching below the structure edge, then an extended field 161 results for each main structure 131 as maximum extension.

The semiconductor substrate 6 below the structure edge can be completely assigned to the extended fields 161 and can thus advantageously be utilized almost completely for the extension of the main structures 131.

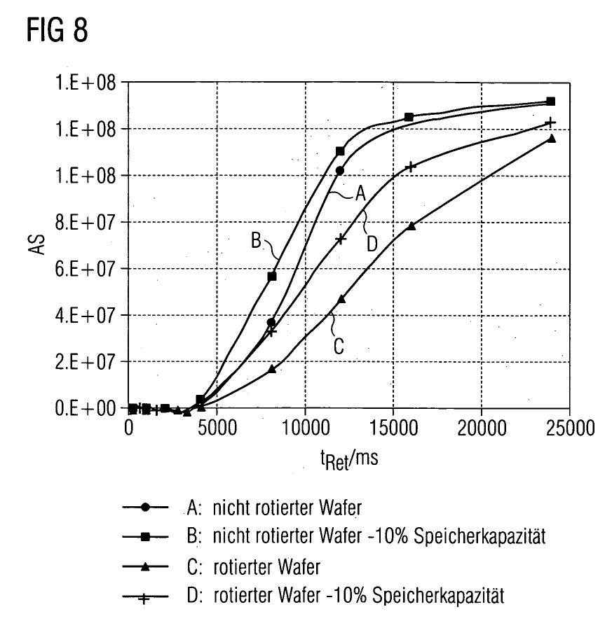

FIG. 8 illustrates the functional dependence of the number of discharged memory cells AS on the time t_{Ret}—referred to as “retention time”—for DRAM modules produced from semiconductor wafers processed in rotated fashion according to the invention and from semiconductor wafers processed in nonrotated fashion. Two DRAM modules in each case were examined for each curve. Curves A and B show the behavior of DRAM modules from semiconductor wafers processed in nonrotated fashion, curve B concerning memory cells having a storage capacitance reduced by 10% compared with the memory cells of curve A. Curves C and D show the behavior in the case of semiconductor wafers processed in rotated fashion according to the invention, curve D again concerning memory cells having a storage capacitance reduced by 10% compared with the memory cells of curve C. The significantly shallower profile of curves C and D compared with curves A and B describes a lengthened “retention time” in the case of semiconductor wafers processed in rotated fashion. The influence of the magnitude of the storage capacitance on the “retention time” also becomes clear from curves B and D. A reduced storage capacitance is accompanied by a decrease in the “retention time”. In a time interval of 128 ms<t_{Ret}<8 sec, the following holds true: AS in the case of semiconductor wafers processed in rotated fashion is approximately 0.5* AS in the case of semiconductor wafers processed in nonrotated fashion.

Thus, according to the invention, before an etching process which expands the main structure in the depth, the longitudinal and transverse extents of main structures in the depth of the semiconductor substrate are oriented in rotated fashion with respect to the x, y axes of the surface grid. As a result, the sections of the semiconductor substrate which are located below secondary structures are made available essentially completely for an extension of the main structures by means of the etching process which expands the main structure in the depth.

As a consequence, significantly larger dimensions and surfaces are possible for the main structures in the depth of the semiconductor substrate. If the main structures are formed in each case as electrical capacitances with electrode areas running along the surface, then it is possible to achieve higher capacitance values in comparison with conventional methods given the same space requirement on the surface of the semiconductor substrate by virtue of the better utilization of a volume of the semiconductor substrate. Given identical capacitance values, a large structure having the main and secondary structures can be embodied in a higher density by the method according to the invention.

The etching process which expands the main structure in the depth is referred to hereinafter, for simplification, as bottle etching process without this effecting a restriction to bottle etching processes in the narrower sense.

The term secondary structures also includes unpatterned sections of the surface of the semiconductor wafer.

One example of an alternate arrangement of main and secondary structures is a checkered arrangement (checkerboard). However, the method according to the invention does not necessarily presuppose the checkered arrangement of main and secondary structures.

The longitudinal and transverse extents of the main structures are oriented in a manner rotated by essentially 45 degrees with respect to the x, y axes of the surface grid. A maximum utilizability of the sections of the semiconductor substrate which are arranged below the secondary structures results in this case. Intermediate walls between adjacent main structures are then formed in cross-sectional planes parallel to the surface of the semiconductor substrate with approximately the same thickness.

The method according to the invention provides an area-selective etching process. To that end, provision is made of the semiconductor substrate comprising a crystalline material which has a crystal lattice with crystal faces that can be differentiated. In suitable etching processes, different etching resistances can be derived from the different properties of the crystal faces. The crystal lattice then has crystal faces that are less resistant to etching and crystal faces that are more resistant to etching.

Preferably, a large structure having at least the main structures is now imaged onto the surface of the semiconductor substrate by means of an exposure device with the x, y axes of the surface grid parallel to the crystal faces that are less resistant to etching.

Preferably, furthermore, the area-selective etching process is controlled in such a way that, in the depth of the semiconductor substrate below a structure edge determined by an extent of the secondary structures into the depth of the semiconductor substrate, primary sidewalls of the main structures that are constructed from the crystal faces that are less resistant to etching are substituted by secondary sidewalls constructed from the crystal faces that are more resistant to etching. The orientation of the crystal faces that are more resistant to etching is rotated in customary semiconductor substrates with respect to the orientation of the crystal faces that are less resistant to etching, so that in this way the orientation—which is intended according to the invention and is rotated with respect to the surface grid—of the longitudinal and transverse extents of the main structure in the depth of the semiconductor substrate is achieved in a particularly advantageous manner.

The large structures are imaged onto the semiconductor substrate by means of a mask having an essentially rectangularly patterned mask layout.

The semiconductor substrate is preferably provided as a semiconductor wafer to be processed in semiconductor process technology. In the processing of the semiconductor wafer, a further advantage of the method according to the invention is exhibited in the fact that only one marking which identifies a crystal orientation in the semiconductor wafer and defines the position of the semiconductor wafer with respect to the mask has to be modified, to be precise in such a way that it is rotated by 45 degrees with respect to the conventional marking and, according to the invention, identifies the orientation of the crystal faces that are less resistant to etching. The processing of the semiconductor wafers, that is to say the process steps of lithography, dry etching and implantation, is then effected unchanged with respect to nonrotated semiconductor wafers corresponding to the prior art.

According to the invention, provision is to be made of the main structures at the surface of the semiconductor substrate in essentially oval fashion.

Monocrystalline silicon is preferably chosen as the material of the semiconductor substrate. For an area-selective etching process in the course of which <100> crystal faces are etched more rapidly than <110> crystal faces, the surface grid is oriented in accordance with a <100> crystal orientation of the monocrystalline silicon.

Preferably, in the course of a further processing of the semiconductor substrate, the main structures are functionally designed as storage capacitances and the secondary structures are essentially designed as selection transistors assigned to the storage capacitances.

The method according to the invention is explained in more detail below using the example of a storage capacitance for a DRAM memory cell:

A mask which prescribes the arrangement at least of main structures is provided with a rectangular pattern for patterning deep trenches each serving as a storage capacitance. The structures on the mask are imaged onto a semiconductor wafer provided with a marking according to the invention, which marking points in the <100> crystal orientation, by means of an exposure device. In this case, the longitudinal side of the imaged rectangles is oriented parallel to the <100> crystal orientation in the semiconductor wafer. The trenches are subsequently etched by means of a dry etching step whose etching speed is dependent on the crystal orientation, in the semiconductor wafer crystal faces with a <100> orientation being etched more rapidly than crystal faces with a <110> orientation. Only crystal faces with a <110> orientation then remain after a specific etching time. By means of a further etching step, the deep trenches etched in the dry etching step are extended in bottle-like fashion below a trench depth of about one micrometer. Above one micrometer, the trenches are provided with an etching-resistant protective layer which prevents lateral etching into regions of the semiconductor substrate which are near the surface.

Before the bottle etching which leads to a bottle-like extension of the trench, the main structure which is produced in the course of the above-described method according to the invention in a semiconductor wafer is an etched trench which has, in an upper section adjoining the surface of the semiconductor wafer, a profile which is oval in plan view, with longitudinal sides parallel to the <100> crystal orientation, that is to say <100> sidewalls. In a lower section below the protective layer, that is to say for instance below one micrometer, the trench has a square profile with <110> sidewalls. In this case, the length of the square diagonals essentially corresponds to the longitudinal extent of the oval profile in the upper part of the structure. The upper oval part of the structure is thus rotated by 45 degrees with respect to the lower square part since the two crystal orientations <100> and <110> are at an angle of 45 degrees with respect to one another.

In the case of a mask layout as used for the production of DRAM modules, the rectangles to be imaged are arranged in checkered fashion. The thickness of an intermediate wall between the sidewalls of the individual trenches is significantly increased compared with the semiconductor wafer processed in nonrotated fashion.

Hereinafter, checkered arrangement is understood to be a pattern in which the rectangles to be imaged on the mask are arranged in rows and are at the same constant distance from one another in each row. The rows are in each case arranged offset with respect to one another in such a way that, in the row lying below or above one row, two rectangles of said one row again have a rectangle situated between them essentially centrally. The distances between the rectangles are chosen such that the rectangles do not touch one another. By virtue of the square cross section and the rotated form of the lower part of the trenches, the volume in the semiconductor wafer is utilized significantly better compared with the conventionally processed semiconductor wafer.

After a further etching step having a duration of about 90 seconds, which brings about a bottle-like extension in the lower section of the trench, the trench in the depth of the semiconductor substrate has a profile that is square in plan view. The thickness of the intermediate walls comprising the semiconductor substrate between the individual trenches is of the order of magnitude of 100 nanometers, instead of about 20 nanometers in the case of semiconductor wafers processed in nonrotated fashion. It is thus possible to etch significantly larger extensions of the trenches, thereby increasing the electrical capacitance of storage capacitances formed from the trenches. Moreover, the square cross section of the lower part of the trenches leads to an optimum filling of the area of the semiconductor wafer in the depth of the semiconductor substrate.

In order to reduce leakage currents in a DRAM cell, comprising a selection transistor and a storage capacitance, the semiconductor wafer from which the DRAM cell is produced is processed according to the method according to the invention.

A similar method for reducing leakage currents is also described in WO 00/02249.

The required size of a storage capacitance depends, inter alia, on the leakage currents that occur. A typical value for a DRAM cell storage capacitance comprising a deep trench is the 40 fF/cell, in which the total cell leakage current is of the order of magnitude of 10 to 15 fA/cell. The latter contains various components, such as, for example, leakage currents through the dielectric, leakage currents along an interface between the semiconductor substrate and a structure that insulates the storage capacitance in the region near the surface (ST1, shallow trench isolation), or leakage currents in the region of the interfaces of source and drain of the selection transistor.

In accordance with the method according to the invention for reducing leakage currents in a DRAM cell having a selection transistor and a storage capacitance, the leakage current along the interface between the semiconductor substrate and the ST1 structure is now significantly reduced. The reduction of the leakage current can be attributed to a lower density of defect locations (trap) along the interfaces oriented according to the invention, since the size of the leakage current is correlated with the number of defect locations and the number of defect locations is reduced in the case of a changed crystal orientation.

A reduction of the total cell leakage current directly decreases the required capacitance. An advantage afforded by a lower capacitance is that the trench depth of the trench serving as capacitance can be reduced. As a result, the etching time could be reduced by the same order of magnitude as the trench depth, thereby significantly increasing the throughput of this process step.

Statistics based on examinations of a plurality of DRAM modules reveal that the total cell leakage currents of a DRAM cell in the case of the semiconductor wafer processed in a manner rotated by 45 degrees according to the invention are reduced by more than 30% compared with the semiconductor wafer processed in nonrotated fashion.

The reduction of the cell leakage current leads to an equivalent increase in the time interval after which the charge in one of the DRAM cells has decreased on account of leakage currents to an extent such that the charge stored in a memory cell has to be refreshed. This time interval is referred to as “retention time”.

A DRAM cell containing a storage capacitance having a structure according to the invention in a semiconductor wafer which has been processed in accordance with the method according to the invention has an increased storage capacitance, reduced leakage currents and thus an increased “retention time”.

The foregoing disclosure of the preferred embodiments of the present invention has been presented for purposes of illustration and description. It is not intended to be exhaustive or to limit the invention to the precise forms disclosed. Many variations and modifications of the embodiments described herein will be apparent to one of ordinary skill in the art in light of the above disclosure. The scope of the invention is to be defined only by the claims appended hereto, and by their equivalents.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

What is claimed is:

1. A method for increasing a structure size of main structures in depth in a semiconductor substrate, comprising:
providing a semiconductor substrate comprising a crystalline material with a crystal lattice with crystal faces that are more resistant to etching and with crystal faces that are less resistant to etching;
arranging main structures on the semiconductor substrate in checkered fashion in a rectangular surface grid, at a surface of the semiconductor substrate, .in each case in alternation with secondary structures formed in each case substantially in a section of the semiconductor substrate that is near a surface thereof;
setting x, y axes of the surface grid to be parallel to the crystal faces that are less resistant to etching; and
performing area-selective etching to increase the structure size of the main structures such that sections of the semiconductor substrate which are located below secondary structures are made available for the formation of extended main structures.

2. The method of claim 1, wherein a large structure having the main structures is imaged onto the surface of the semiconductor substrate by means of an exposure device with the x, y axes of the surface grid parallel to the crystal faces of the semiconductor substrate that are less resistant to etching.

3. The method of claim 2, wherein prior to imaging, a mask having a rectangularly patterned mask layout of the large structure is oriented in accordance with the crystal faces of the semiconductor substrate that are less resistant to etching.

4. The method of claim 1, wherein a semiconductor wafer is provided as the semiconductor substrate and a marking identifying a crystal orientation of the crystal lattice is provided at and/or on the semiconductor wafer.

5. The method of claim 4, wherein a crystal orientation identifying the orientation of the crystal faces that are less resistant to etching is identified by the marking.

6. The method of claim 5, wherein the marking is used for the orientation of a mask in an exposure device.

7. The method of claim 1, further comprising providing the main structures at the surface of the semiconductor substrate with an oval cross section.

8. The method of claim 1, wherein monocrystalline silicon is provided as the material of the semiconductor substrate.

9. The method of claim 8, wherein the surface grid is oriented in accordance with a <100> crystal orientation of the monocrystalline silicon.

10. The method of claim 9, wherein during the area-selective etching, the <100> crystal faces having a lower etching resistance are etched more rapidly than the <110> crystal faces that are more resistant to etching.

11. The method of claim 1, wherein the main structures, in upper sections between the surface of the semiconductor substrate and at least one lower edge of the secondary structures, are provided with a protective layer that is resistant at least toward the expanding etching process.

12. The method of claim 1, wherein the main structures are functionally designed as storage capacitances.

13. The method of claim 1, wherein the secondary structures are functionally designed as selection transistors assigned to the storage capacitances.

14. A semiconductor substrate structure, comprising:
a trench with a profile that is oval in plan view in an upper section adjoining the surface of the semiconductor substrate, with longitudinal sides parallel to the <100> crystal orientation, and with a profile that is essentially rectangular in a lower section below an etching-resistant protective layer, with longitudinal sides parallel to the <110> crystal orientation.

15. The structure of claim 14, wherein the protective layer extends up to a maximum of 1 micrometer below the surface of the semiconductor substrate.

16. The structure of claim 14, wherein the trench has, in the lower part, a bottle-like extension with a profile that is square in plan view and sides parallel to the <110> crystal orientation.

17. An arrangement of structures each consistent with the structure of claim 14, wherein the thickness of intermediate walls remaining between adjacent structures in the semiconductor substrate is of the order of magnitude of 100 nm.

18. The arrangement of claim 17, wherein the structures are designed as storage capacitances.

19. The arrangement of claim 17, wherein the structures comprise at least portions of DRAM cells.

20. The arrangement of claim 19, wherein the structures comprise storage capacitances.
